(19) United States
(12) Patent Application Publication
(10) Pub. No.: US 2023/0200270 A1
(43) Pub. Date: Jun. 22, 2023

(54) SELECTIVE STOP TO CONTROL HEATER HEIGHT VARIATION

(71) Applicant: International Business Machines Corporation, Armonk, NY (US)

(72) Inventors: Prasad Bhosale, Albany, NY (US); Kangguo Cheng, Schenectady, NY (US); Takashi Ando, Eastchester, NY (US)

(21) Appl. No.: 17/555,740

(22) Filed: Dec. 20, 2021

(51) Int. Cl. H01L 45/00; H01L 27/24

(52) U.S. Cl. CPC H01L 45/126; H01L 27/2463; H01L 45/06; H01L 45/16

(57) ABSTRACT

A method, phase change memory array, and system for controlling heater height variation in phase change memories using a multi-step selective stop method. The method may include depositing a first dielectric layer. The method may also include depositing a second dielectric layer proximately connected to the first dielectric layer, where the second dielectric layer is different than the first dielectric layer. The method may also include depositing a heating material. The method may also include performing a first selective stop to remove excess heating material above the second dielectric layer. The method may also include performing a second selective stop to remove the second dielectric layer.

### BACKGROUND

The present disclosure relates to phase change memories and, more specifically, to controlling heater height variation in phase change memories using a multi-step selective stop method.

Phase change memory (PCM) is a non-volatile random access memory (NVRAM). PCMs contain phase-change materials (such as alloys containing Tellurium) and may alter the states (e.g., crystalline and amorphous phases) of the PCM using heat. The phase-change materials may be placed between two electrodes, and when the phase-change materials are in a crystalline state the phase-change materials have a high conductivity and a low resistivity (which corresponds to a logical 1), allowing current to travel quickly thorough the phase-change materials and between electrodes. When the phase-change materials are in an amorphous state, the materials have a low conductivity and a high resistivity (which corresponds to a logical 0), preventing current from travelling quickly through the phase-change materials and between the electrodes. The portions of the phase-change material that are amorphous and crystalline may be controlled to achieve intermediate conductivity values, for use in analog computing. The data is stored using the contrast between resistances of the multiple states. The PCM is a non-volatile memory, as the states can remain if/when power is removed, allowing PCMs to retain data even when there is no power.

### SUMMARY

The present invention provides a method, phase change memory array, and system to control heater height variation in phase change memories using a multi-step selective stop method. The method may include depositing a first dielectric layer. The method may also include depositing a second dielectric layer proximately connected to the first dielectric layer, where the second dielectric layer is different than the first dielectric layer. The method may also include depositing a heating material. The method may also include performing a first selective stop to remove excess heating material above the second dielectric layer. The method may also include performing a second selective stop to remove the second dielectric layer.

The phase change memory array with minimal variation between heater height may be formed by depositing a first dielectric layer. The phase change memory array may also be formed by depositing a second dielectric layer proximately connected to the first dielectric layer, where the second dielectric layer is different than the first dielectric layer. The phase change memory array may also be formed by depositing a heating material. The phase change memory array may also be formed by a first selective stop to remove excess heating material above the second dielectric layer. The phase change memory array may also be formed by performing a second selective stop to remove the second dielectric layer.

The system may include a phase change memory array with minimal variation between heater height. The phase change memory array may be formed by depositing a first dielectric layer. The phase change memory array may also be formed by depositing a second dielectric layer proximately connected to the first dielectric layer, where the second dielectric layer is different than the first dielectric layer. The phase change memory array may also be formed by depositing a heating material. The phase change memory array may also be formed by a first selective stop to remove excess heating material above the second dielectric layer. The phase change memory array may also be formed by performing a second selective stop to remove the second dielectric layer.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a partially formed phase change memory array prior to performing a selective stop, according to some embodiments.

FIG. 2A depicts a cross-sectional view of a partially formed phase change memory array after performing selective stop, according to some embodiments.

FIG. 2B depicts a top down view of the partially formed phase change memory array after performing selective stop, according to some embodiments.

FIG. 3A depicts a cross-sectional view and dimensions of a formed phase change memory heater, according to some embodiments.

FIG. 3B depicts a top-down view and dimensions of a formed phase change memory heater, according to some embodiments.

FIG. 4 depicts an exemplary fully formed phase change memory, according to some embodiments.

FIG. 5A depicts an intermediate step of forming a phase change memory array, according to some embodiments.

FIG. 5B depicts the dimensions of the phase change memory portion of the phase change memory array, according to some embodiments.

FIG. 6A depicts an intermediate step of forming a phase change memory array after a first selective stop, according to some embodiments.

FIG. 6B depicts the dimensions of the phase change memory portion of the phase change memory array after the first selective stop, according to some embodiments.

FIG. 7A depicts a phase change memory array after a second selective stop, according to some embodiments.

FIG. 7B depicts the dimensions of the phase change memory portion of the phase change memory array after the second selective stop, according to some embodiments.

FIG. 8 depicts a flowchart of an exemplary method of forming a phase change memory array using selective stop, according to some embodiments.

FIG. 9 depicts a block diagram of a sample computer system, according to some embodiments.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to phase change memories and, more specifically, to controlling heater height variation in phase change memories using a multi-step selective stop method. While the present disclosure is not necessarily limited to such applications, various aspects of the disclosure may be appreciated through a discussion of various examples using this context.

A phase change memory (PCM) may include a bottom electrode and a top electrode with a phase change material between the two. As discussed above, conventional phase change memories (PCMs) and their corresponding phase change materials have two states—amorphous and crystalline. The amorphous state may be referred to as a RESET state and the crystalline state may be referred to as a SET state. To switch the phase change material between the two states, the PCM may also include a heater (sometimes called the bottom electrode and/or the bottom electrode contact) that sends current pulses from the heater into the phase change material. In some embodiments, the heater is the bottom electrode. In some embodiments, the heater is patterned on top of the bottom electrode. In these instances, the current pulses may originate in the bottom electrode, be transmitted through the heater, and then transmit into the phase change material.

When the phase change material is in a crystalline state, the heater may convert the material into an amorphous state by sending short high current pulses to rapidly heat the phase change material and then quenching or cooling it. When the phase change material is in an amorphous state, the heater may convert the material into a crystalline state by sending a longer, but lower current, pulse(s) to heat the phase change material to a crystallization temperature for a prolonged period of time (without cooling the material) to allow for the material to become crystalline.

When the phase change material (of the phase change memory) is in an amorphous state (or a RESET state, as it is sometimes referred to), the phase change material may have a high resistivity and a low conductivity (i.e., high electrical resistivity and low electrical conductivity), and current may not travel quickly through the phase change material. Alternatively, when the phase change material is in a crystalline state (or a SET state, as it is sometimes referred to), the phase change material may have a low resistivity and a high conductivity (i.e., low electrical resistivity and high electrical conductivity), and current may travel quickly through the phase change material. The data may be stored in the phase change memory (PCM) using the contrast between the resistances of the two states (or phases). Further, each state may correspond to a binary value, with an amorphous state corresponding to a 0 and a crystalline state corresponding to a 1. PCM has many benefits, such as increased speeds (compared to other types of memory), non-volatile capabilities, less power requirements, etc., however, conventional PCMs may have abrupt changes between the phases, particularly at the amorphous state (i.e., an abrupt change to the RESET state).

Resistance, as referred to herein, may be an electrical resistance, and may refer to the opposition of current flow through an object. Resistivity, as referred to herein, may be an electrical resistivity, and may refer to the resistance (i.e., electrical resistance) per unit area of an object and/or material. Resistivity may, for example, be calculated using the magnitude of the electric field and the magnitude of the current density (i.e., the magnitude of the electric field divided by the magnitude of the current density). Resistance may be calculated, for example, by multiplying the resistivity by the length of the object and/or material and dividing by the cross-sectional area of the object and/or material. When resistivity remains constant, the resistance of an object can be changed by changing the length, width, etc. of the object. For example, a titanium nitride (TiN) material may have different amounts of resistance depending on the length, width, etc. of the TiN object, however the resistivity of TiN does not change due to changes in the dimensions of the object formed by the TiN.

Similarly, conductance, as referred to herein, may be an electrical conductance, and may refer to the ease of current flow through an object (i.e., how easily current flows through an object). Conductivity, as referred to herein, may be an electrical conductivity, and may refer to the conductance (i.e., electrical conductance) per unit area of an object and/or material. When conductivity remains constant, the conductance of an object can be changed by changing the length, width, etc. of the object. Resistivity and conductivity are intrinsic properties, whereas resistance and conductance are extrinsic properties.

In PCMs, when current travels through the heater, heat is generated (for instance, through the Joule heating effect) and the heat can change the phase of the phase change material from a crystalline to an amorphous phase (or vice versa, depending on the amount of heat and whether there is a quench). Therefore, the greater the electrical conductance or the lesser the electrical resistance (referred to herein as conductance and resistance, respectively), the greater the flow of current (at a particular voltage) traveling through the heater and the greater the amount of heat generated from the flowing current.

In some instances, a system and/or device within a system may include an array of phase change memories (PCMs) or phase change memory cells. The array may include a plurality of phase change memories. In some instances, other non-phase change memory components may also be included in the array. However, in conventional systems and/or devices, the heights of the heaters for each PCM cell may vary. Variation in PCM heater height may lead to significant performance drift for the PCM cell and the device/system as a whole over time. For instance, the variation in heater height may cause a fluctuation in heater performance for the PCM array, as each heater performs slightly differently. Heaters with different heights may have different thermal masses, which may result in the heater with the higher thermal mass (the taller heater) to take longer to heat up (particularly between the bottom electrode and the phase change material) and may delay efficient heat transfer for the taller heater, as heat may not be transferred efficiently through the heater until it has heated up (which, as mentioned, takes longer for a taller heater). This may cause some heaters to take longer to SET or RESET than other heaters in the PCM array and each PCM in the PCM array to act/perform differently (or at least slightly differently). For example, with a heater with a slightly shorter height, current may reach the phase change material more quickly and the phase change material may change from crystalline to amorphous (or vice versa) more quickly than another PCM cell with a heater with a greater height. As the PCM cells continue to perform, the states of the phase change materials in the PCM cells may become increasingly unequal with each other due to the varying heights. This may cause the PCM cells to become less in sync and may cause performance drift between the PCM cells.

The present disclosure provides a method, system, and phase change memory array to control heater height variation in phase change memories using a multi-step selective stop method. By controlling the heater height for each PCM, or PCM cell, the height may be less varied and the performance may be more consistent between PCMs in the system. To control the heater height and minimize the variation between heaters, a multi-step selective stop process may be used. Further, a bi-layer dielectric (i.e., two layers of dielectric) is used as heater dielectric to control the heater height. Specifically, a first step is performed (i.e., a first selective stop) to polish and remove excess metal from the heater formation, stopping on a first layer of dielectric. Then, a second step is performed (i.e., a second selective stop) to polish and remove the first layer of dielectric (a sacrificial dielectric) through a high selectivity chemical mechanical planarization, also referred to as chemical mechanical polishing. Having the bi-layer dielectric allows for a dielectric layer to remain after the selective stop process while also providing a sacrificial dielectric to be removed during the selective stop process, which can create a more uniform heater height among the different heaters in the PCM array. The multi-step selective stop may be extremely precise, resulting in heater heights with minimal to no variation. This process is further discussed herein.

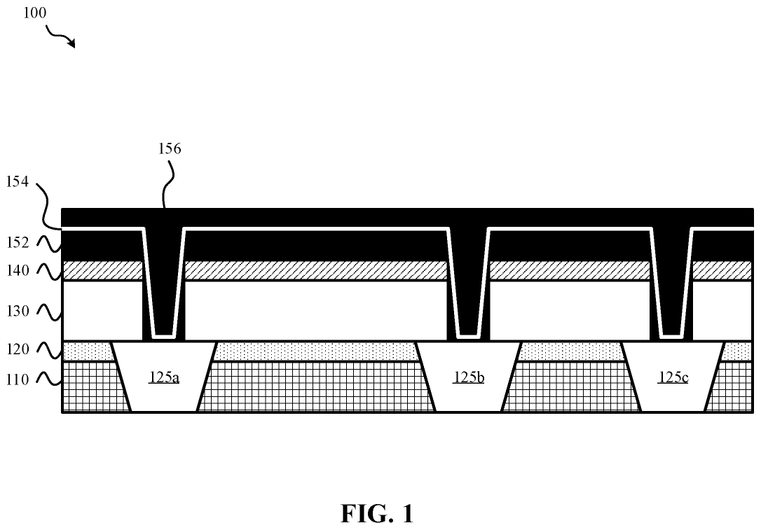

Referring now to FIG. 1, a cross-section view of a partially formed phase change memory array 100 is depicted, according to some embodiments. Partially formed phase change memory array 100 may also be referred to herein as intermediate phase change memory array 100. Intermediate phase change memory array 100 shows the components of the array prior to the performing of any selective stop processes. In some embodiments, intermediate phase change memory array 100 is a plurality of phase change memory cells on the same computer chip and/or wafer within the computer system.

Partially formed phase change memory (PCM) array 100 includes bottom electrodes 125a, 125b, and 125c. Partially formed PCM array 100 also includes multiple layers of insulator materials. Specifically, partially formed PCM array 100 may include a silicon carbide (SiC) layer 110, a tetraethyl orthosilicate (TEOS) layer 120, a silicon dioxide (SiO₂) layer 130, and a silicon nitride (SiN) layer 140. In some instances, the SiC layer 110 may be a nitrogen doped SiC, such as NBLOK™. These materials are just example materials of different dielectrics that may be used in the phase change memory array. Any type, or any number, of dielectric(s) may be used to surround and protect bottom electrodes 125 and any other components of the phase change memory array. In some embodiments, the SiN layer 140 is used as a sacrificial layer that will be removed (discussed further herein) during a selective stop process such as chemical mechanical polishing (CMP). Chemical mechanical polishing may also be referred to herein as chemical mechanical planarization.

Having different layers of insulator and using different materials for each layer may help more accurately etch and/or stop etching at each layer. For instance, each different material may utilize different chemistry and/or different processes of removal, therefore the process that removed the previous layer may not be effective at removing the next layer. For example, SiO₂ has a low thermal conductivity whereas SiN has a high thermal conductivity. Because of this, a process that is effective at removing the SiN layer 140 may not be as effective at removing the SiO₂ layer 130 and it may be easier to selectively stop on the proper layer/height.

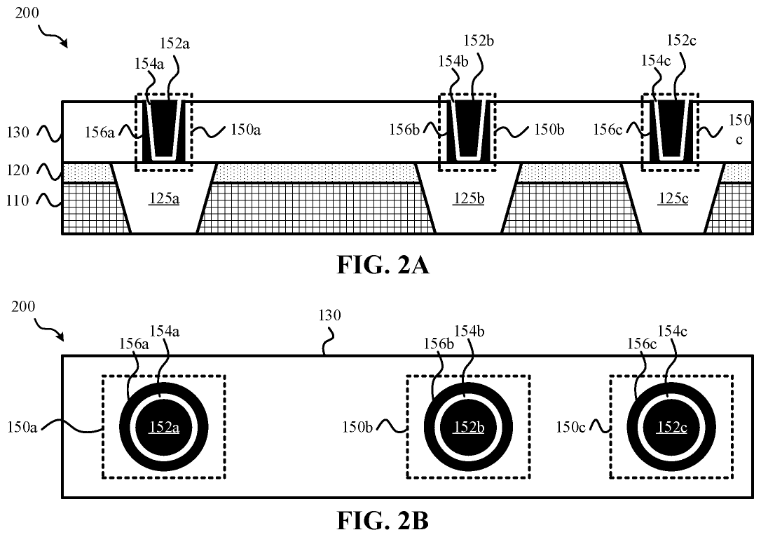

Intermediate PCM array 100 also includes layers of heating material that will, as depicted in FIG. 2A, become the heater(s). The layers of heating material include heating layer 152, heating layer 154, and heating layer 156. In some instances, as depicted, heating layers 152 and 156 may be a same material, such as tantalum nitride (TaN), and heating layer 154 may be a different material, such as titanium nitride (TiN). In some instances, heating layers 152, 154, and 156 may each be a different material. In some instances, heating layers 152, 154, and 156 may all be a same material. Heating layers 152, 154, and 156 may be made of material(s) such as TiN, TaN, tungsten (W), WN, or any other conductive materials.

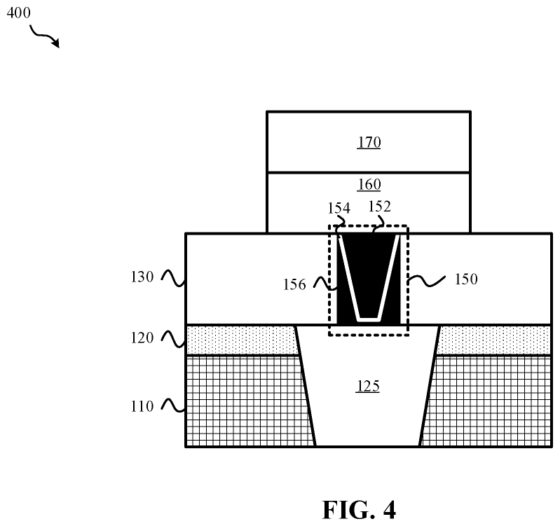

To remove excess material as well as control the heater height (thus reducing and/or eliminating any variation in heater height), a multi-step selective stop process may be used. Selective stop, as referred to herein, may be the selective removal of materials and/or layers in the partially formed PCM array 100. By selectively removing a material and/or layer, instead of removing all the necessary materials/layers in a single step, the removal process may be more accurate and consistent between the different PCMs in the PCM array. Further, as discussed herein and depicted in FIG. 4B, there may be very specific design dimensions used in the PCM array. By using specific design dimensions, the selective stop may be even more precise.

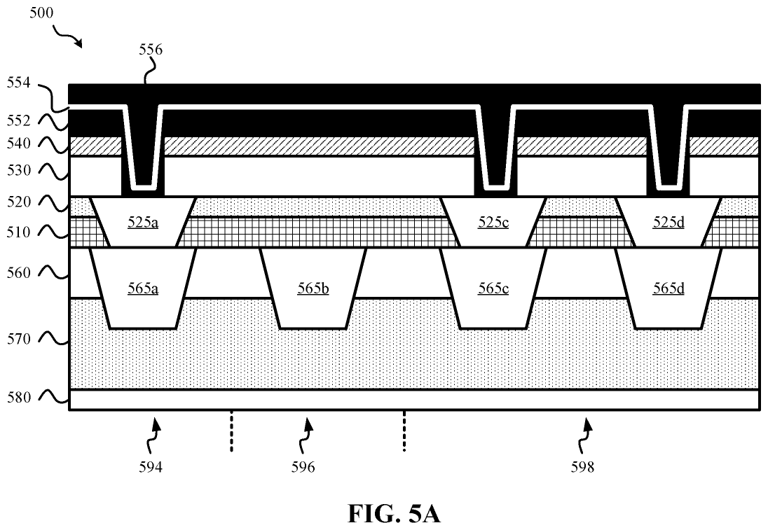

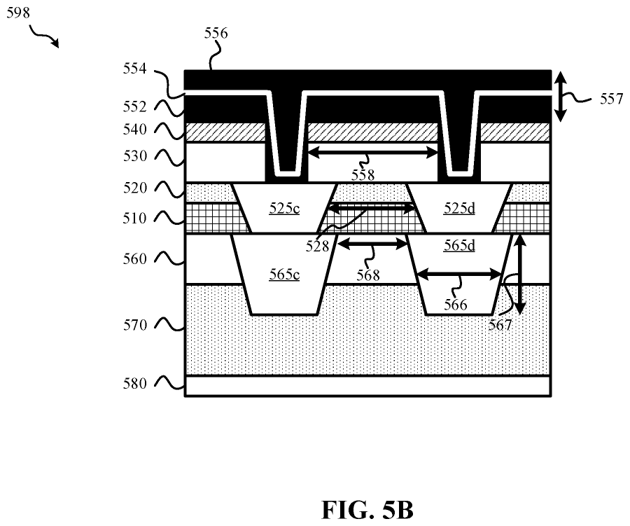

In some instances, the selective stop process may be a two step process. The first step may be to remove excess material from the heater layers 152, 154, and 156. However, the removal process may stop once it reaches SiN layer 140. Then, the second step in the selective stop process may be to remove SiN layer 140, as SiN layer 140 may be a sacrificial layer. Once SiN layer 140 is removed, the heaters may be at a proper height with minimal to no variation. The selective stop process is discussed further herein and depicted in FIGS. 5A-7B.

Referring now to FIG. 2A, a cross-sectional view of a phase change memory array 200 after performing selective stop is depicted, according to some embodiments. In some embodiments, PCM array 200 may be PCM array 100 (FIG. 1) after both selective stop steps have been performed. PCM array 200 depicts three PCM cells. A first PCM cell may include bottom electrode 125a as well as a heater 150a made up of layers 152a, 154a, and 156a. The second PCM cell may include bottom electrode 125b as well as a heater 150b made up of layers 152b, 154b, and 156b. The third PCM cell may include bottom electrode 125c as well as a heater 150c made up of layers 152c, 154c, and 156c. PCM array 200 depicts a gap between heater 150a and 150b. This may be to leave space for other non-PCM components of the chip and/or wafer, in some instances. In some instances, the heaters 150 may all be evenly spaced (not depicted).

Because the heaters 150 are formed using a multi-step (for example, a two-step) selective stop (discussed further herein), the heaters 150 may have minimal variation between height, which may improve the performance of systems with a phase change memory array 200. Further, as depicted in FIG. 2A, the heaters 150 and the bottom electrodes 125 are surrounded by the various insulator layers (SiC layer 110, TEOS layer 120, and SiO₂ layer 130) to protect each PCM cell and prevent heat generated by the bottom electrodes 125 from transmitting to the other PCM cells.

FIG. 2B depicts a top down view of the partially formed phase change memory array 200, or intermediate phase change memory array 200, after performing selective stop, according to some embodiments. As depicted, heaters 150a, 150b, and 150c (referred to collectively has heaters 150) may include a plurality of layers of material. These layers may be in a ring shape. In this instance, heaters 150 include three layers—152, 154, and 156. In some instances (not depicted), heaters 150 may include a single layer, two layers, or any number of layers. As mentioned above, in some instances, heating layer 152 may be TaN, heating layer 154 may be TiN, and heating layer 156 may also be TaN. In some instances, each heating layer 152, 154, and 156 may be a different material such as TiN, TaN, and W, for example.

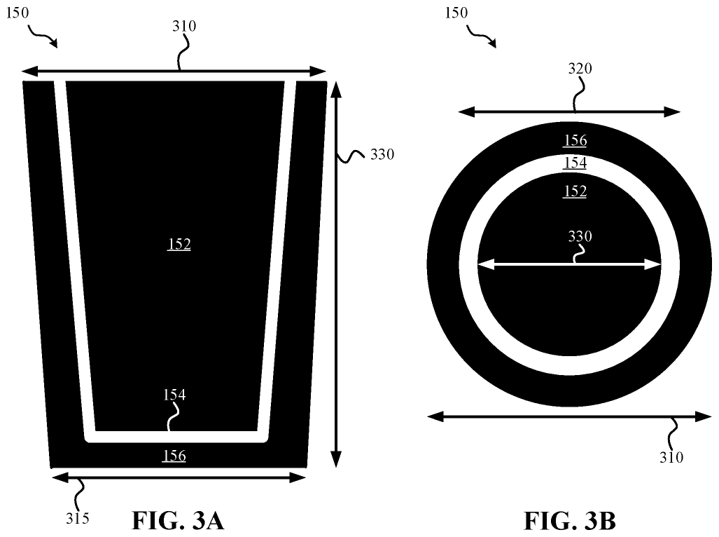

Referring now to FIG. 3A, a cross-sectional view and dimensions of a formed phase change memory heater 150 is depicted, according to some embodiments. Phase change memory heater 150 may be the same heater 150 depicted in FIGS. 2A and 2B, in some instances. FIGS. 3A and 3B give example views and example dimensions of a heater within a phase change memory array, however the actual size/dimensions of the heater may vary depending on the specific phase change memory array. For example, layer 156 may have a thickness between 2-8 nanometers (nm), layer 154 may have a thickness between 3-10 nm, and layer 152 may fill the remainder of the opening. This may result in a heater with an average thickness/width between 7-50 nm, in some instances. As mentioned herein, it is desirable to have minimal variation between heater heights for each heater in a phase change memory array. To achieve minimal variation between heater heights, a precise multi-step selective stop method may be performed. This may result in each heater 150 having a cross-sectional heater height 330 of 75 nanometers (nm), top width 310 of 32 nm, and bottom width 315 of 25 nm. There may be minimal to no variation of these dimensions across the multiple heaters.

FIG. 3B depicts a top-down view and dimensions of a formed phase change memory heater, according to some embodiments. The heater layer 156 diameter 310 is the same measurement as cross-sectional top width 310 of FIG. 3A, and measures 32 nm. Additionally, the diameter 320 of heater layer 154 is 27 nm and the diameter 330 of heater layer 152 is 21 nm. This may result in, at the top portion of the heater 150, layer 156 having a thickness of 5 nm, layer 154 having a thickness of 6 nm, and layer 152 having a thickness of 21 nm.

Referring now to FIG. 4, an exemplary fully formed phase change memory cell 400 is depicted, according to some embodiments. The phase change memory cells and phase change memory arrays may be discussed herein in relation to the heater and the heater height. However, the phase change memory cells may not be fully formed until they include a phase change material and a top electrode. Phase change memory (PCM) cell 400 depicts a fully formed PCM cell 400 with a phase change material 160 and a top electrode 170. In phase change memory cell 400, current may be exchanged between bottom electrode 125 and top electrode 170. This current may travel through the heater 150 and into the phase change material 160, and the heat generated from the current may change the phase change material 160 from a crystalline phase to an amorphous phase, or vice versa.

In some embodiments, each phase change memory cell 400 in a phase change memory array may have its own phase change material 160 and top electrode 170. For example, in phase change memory array 200 (FIG. 2A), there may be a phase change material and a top electrode on top of heater 150a, a phase change material and a top electrode on top of heater 150b, and a phase change material and a top electrode on top of heater 150c. In some instances (not depicted), there may be dielectric surrounding the sides of the phase change material 160 and top electrode 170 to protect the phase change material 160 and top electrode 170 and prevent heat from travelling to the other phase change memory cells. There may also, in some instances, be dielectric on a top portion of top electrode 170.

Referring to FIG. 5A, an intermediate step 500 of forming a phase change memory array is depicted, according to some embodiments. Intermediate step 500 may also be referred to as intermediate phase change memory array 500 or a partially formed phase change memory 500, herein. The array 100 (in FIG. 1) depicts a simpler array, however the phase change memory array may include any number of components. Therefore, phase change memory array 500 depicts a more complex array with more components and more component stacks within the array. In addition, as depicted in FIG. 5A (and discussed below), although it is referred to herein as a phase change memory array, the phase change memory array may include additional components that are not phase change memory components. For instance, the term phase change memory (PCM) array may refer to a chip and/or wafer with phase change memory cells and other components, such as non-PCM components (including non-PCM memory cells). Intermediate PCM array 500, for instance, includes a dummy fill area 594, a non-PCM area 596, and a PCM area 598. Dummy fill area 594, non-PCM area 596, and PCM area 598 may all be part of the intermediate phase change memory array 500 as they may all be located on a same chip and/or wafer, for example. Further, FIG. 5A demonstrates that there may be additional components to the PCM area 598 below the bottom electrode (for instance, as compared to FIG. 1, where the bottom electrode is not on top of any other components). In some instances (not depicted), there may be a plurality of additional components below the bottom electrode 525.

The phase change memory (PCM) area 598 of the intermediate PCM array 500 is the portion of the intermediate PCM array 500 that will include phase change memory cells once the PCM array is fully formed. Specifically, PCM area 598 includes two bottom electrodes, 525c and 525d, as well as layers 552, 554, and 556 (that will become heaters in later steps, discussed herein). Although PCM area 598 depicts two bottom electrodes 525 which will, once the PCMs are fully formed in later steps (discussed herein), correspond to two PCMs, PCM area 598 may include any number of bottom electrodes and PCMs. In some instances, the bottom electrodes 525c and 525d are connected to various components. For example, FIG. 5A depicts bottom electrodes 525 are on top of (i.e., proximately connected to) components 565. Components 565a-d (referred collectively as components 565) may be additional components in the PCM array. In some instances, not depicted, there may be additional components of the PCM array that are below components 565 or above layer 556.

As depicted in FIG. 5A, partially formed PCM array 500, or intermediate PCM array 500, also has a non-PCM area 596. This area may include one or more components or stacks of components that are included in the chip and/or wafer and are not related to phase change memories. In intermediate PCM array 500, non-PCM area 596 includes component 565b. Component 565b may be a substrate, electrode, connector, etc., for example. In some instances, as depicted, each stack may have a component 565. For the PCM area 598, component 565 may be a non-PCM component that the PCM is stacked on top of. For example, component 565 may be a connector to other components that are not depicted. In this example, component 565 may not be a PCM component, but may connect the PCM components (such as bottom electrode 525) to other portions of the chip and/or wafer. Non-PCM area 596 may not have a bottom electrode 525, and may not have layers 552, 554, and 556 proximately connected to the bottom electrode. This is because the non-PCM area 596 may have no need for a heater nor a bottom electrode, as it is not transmitting current from a bottom electrode to change the phase of a phase change material (not pictured).

However, because non-PCM area 596 may not have a bottom electrode 525 and may not have layers 552, 554, and 556 proximately connected to the bottom electrode 525, there may be more risk of heater height variation and variation in the layers as there is an open area (non-PCM area 596) where heaters are not being formed. To help prevent heater height variation, the PCM array may include a dummy area 594, as depicted in FIG. 5A. The dummy area 594 includes a dummy stack, including a dummy bottom electrode 525a. The term dummy, as referred to herein, refers to having no functionality and the term dummy component refers to a component having no functionality. Therefore, the dummy bottom electrode 525a may be a dummy component that has no functionality within the PCM array 500. In some instances, the dummy bottom electrode 525a may be made of a different material (with a same/similar density, in some instances) that may not function the same as a conventional bottom electrode. In some instances, for example, current may not be transmitted through dummy bottom electrode 525a. Instead, the dummy bottom electrode 525a may offer structural support to help prevent any sagging or variation in height (or other dimensions) of the various components of the PCM array 500. For example, if dummy area 594 was instead another non-PCM area, then there may be significant areas with no components, which could cause the layers 510, 520, 530, 540, 560, 570, etc. to sink/sag over time. Further, in partially formed PCM array 500, dummy area 594 may allow for a more frequent formation of heaters (as opposed to heaters only being formed in the PCM area 598) which may help prevent heater height variation due to infrequent formation of heaters.

In intermediate PCM array 500, dummy bottom electrode 525a is on top of (i.e., proximately connected to) component 565a. In some instances, component 565a is a dummy component that is part of the dummy stack. In these instances, the entire dummy area 594 may be a non-functional area that provides no function to the PCM array 500. In some instances, component 565a functions the same/similar to component 565b in the non-PCM area 596. In these instances, although component 565a is in the dummy area 594 of the PCM array 500, component 565a may be a functioning component within the array.

The term “proximately connected” may be used herein to describe a connection between two components, specifically components that are directly connected to or touching each other. For example, component 565 may be described as proximately connected to bottom electrode 525. Further, layers 570, 560, and 510 may all be described as proximately connected to component 565. However, component 565 may not be described as proximately connected to heating layer 552, as bottom electrode 525 separates heating layer 552 and component 565, so the two are not directly connected. Thus, even though component 565 may have an electrical connection to both bottom electrode 525 and heating layer 552, component 565 is more directly connected to bottom electrode 525. By this reasoning, therefore, component 565 is proximately connected to the bottom electrode 525, as illustrated.

Intermediate PCM array 500 includes multiple layers of various materials. Specifically, intermediate PCM array 500 includes a silicon carbide (SiC) layer 510, a tetraethyl orthosilicate (TEOS) layer 520, a silicon dioxide (SiO₂) layer 530, and a silicon nitride (SiN) layer 540. These layers may be the same/similar to layers 110, 120, 130, and 140 from partially formed PCM array 100 (FIG. 1). In addition, intermediate PCM array 500 includes additional dielectric layers 560 and 570. In some instances, both layers 560 and 570 are materials such as TEOS. In some instances, layers 560 and 570 may be different materials such as SiC, TEOS, SiO₂, SiN, etc. For example, layer 560 may be SiN and layer 570 may be TEOS. Layers 510, 520, 530, 540, 560, and 570 may all be various types of dielectric in order to protect the components of the PCM array 500. These layers 510, 520, 530, 540, 560, and 570 are on top of a substrate 580. Substrate 580 may be a semiconductor substrate, in some instances. In some instances, the substrate 580 may include other devices and/or components such as transistors, isolation structures, contacts, etc.

To form intermediate PCM array 500, layer 570 may be deposited on top of the substrate 580 and layer 560 may be deposited on top of layer 570. These layers may be deposited through atomic layer deposition (ALD), chemical vapor deposition (CVD), laser induced chemical vapor deposition (LCVD), or any other applicable deposition technique. Once both layers 560 and 570 are deposited/formed, opening(s), or via(s), may be patterned (for example, etched) into the layers 560 and 570. These opening(s)/via(s) create space for the components 565. In intermediate PCM array 500, four openings/vias may be created—one for each component 565 (i.e., 565a, 565b, 565c, and 565d). However, an intermediate PCM array may include any number of openings and components. Once the openings are created, components 565 may be deposited and/or formed in the openings. In some instances, any excess material from the deposition of the components 565 may be removed via etching, chemical mechanical polishing (CMP), etc. Chemical mechanical polishing may also be referred to as chemical mechanical planarization.

Next, layer 510 may be deposited on top of layer 560 and components 565, and layer 520 may be deposited on top of (i.e., proximately connected to) layer 510. As mentioned herein, layer 510 may be a SiC layer and layer 520 may be a TEOS layer, in some instances. These layers may be deposited through atomic layer deposition (ALD), chemical vapor deposition (CVD), laser induced chemical vapor deposition (LCVD), or any other applicable deposition technique. Once both layers 510 and 520 are deposited and/or formed, openings may be patterned into layers 510 and 520. Bottom electrodes 525 may be deposited and/or formed in each of the openings. In some instances, the bottom electrode may be formed using a complementary metal-oxide semiconductor (CMOS) back end of the line (BEOL) damascene process. In intermediate PCM array 500, only three openings may be patterned as there are only three bottom electrodes 525 in the intermediate PCM array 500. This is because non-PCM area 596 may not have any use for a bottom electrode as this area may not include any sort of phase change memory. In some instances, as discussed herein, the bottom electrode 525a may be a dummy bottom electrode and may not have any functionality. Once the bottom electrodes 525 are in place, any excess material from the deposition of the bottom electrodes 525 may be removed via etching, chemical mechanical polishing (CMP), etc., in some instances.

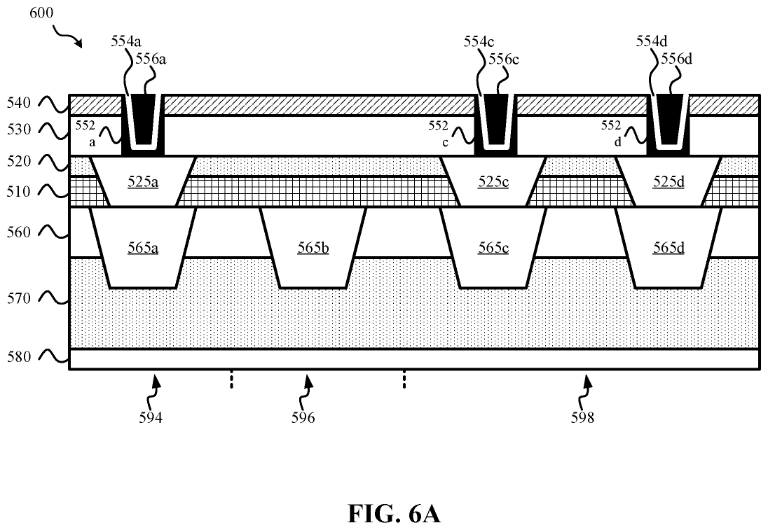

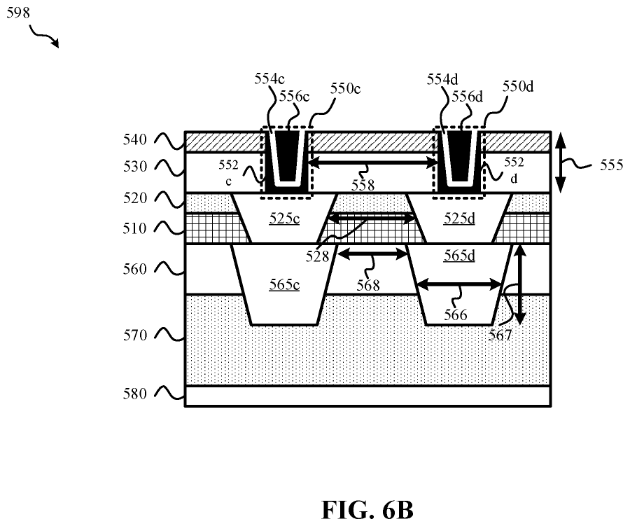

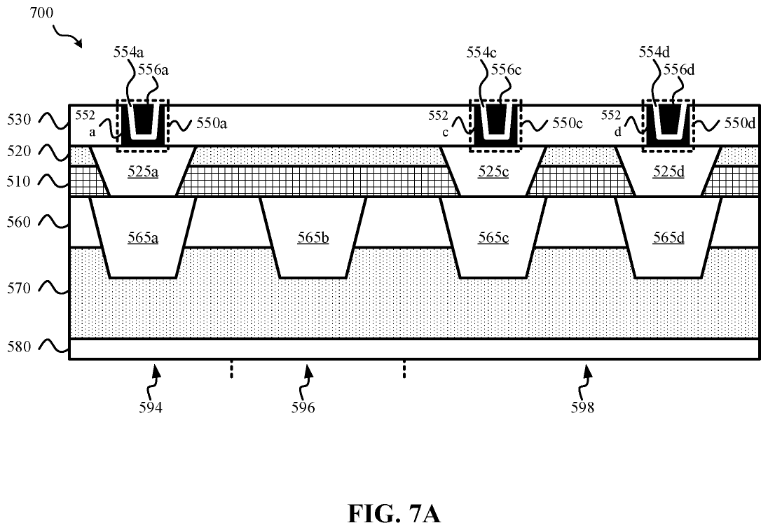

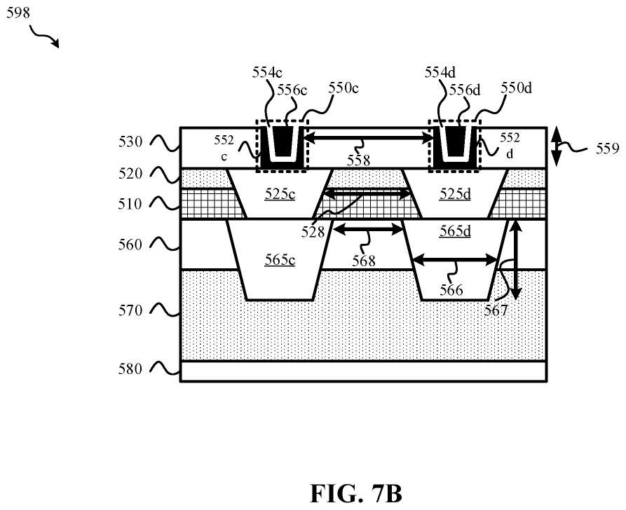

When forming intermediate PCM array 500, once the bottom electrodes 525 are in place and, in some instances, once any excess material is removed, layer 530 may be deposited on top of layer 520 and bottom electrodes 525 and layer 540 may be deposited on top of layer 530. As discussed herein, layer 530 may be a SiO₂ layer and layer 540 may be a SiN layer. Both layers 530 and 540 may be layers of dielectric. The dielectric layers may protect the heater (formed from layers 552, 554, and 556) and the other components and may help prevent heat transfer to and from the heater to other external components. Further, by using different dielectric materials for each layer 530 and 540, the chemistry used to polish and/or remove either layer can be very selective and only specific layers may be removed (discussed further herein in relation to FIGS. 6A and 7A). In some instances, SiO₂ layer 530 and SiN layer 540 may be deposited through atomic layer deposition (ALD), chemical vapor deposition (CVD), laser induced chemical vapor deposition (LCVD), or any other applicable deposition technique.

Once layers 530 and 540 are deposited, openings, or vias, may be etched in layers 530 and 540 (for example, through reactive ion etching (RIE)). These openings are where the heaters (formed from layers 552, 554, and 556) will be in the formed PCM array. Heating layers 552, 554, and 556 may be deposited in the created opening. In some instances, as depicted, heating layers 552 and 556 may be a same material, such as tantalum nitride (TaN), and heating layer 554 may be a different material, such as titanium nitride (TiN). In some instances, heating layers 552, 554, and 556 may each be a different material. In some instances, heating layers 552, 554, and 556 may all be a same material. Heating layers 552, 554, and 556 may be made of material(s) such as TiN, TaN, tungsten (W), WN, or any other conductive materials. Heating layers 552, 554, and 556 may be the same/similar to heating layers 152, 154, and 156 (FIG. 1A), in some instances. In some instances, each layer 552, 554, and 556 may be depositing individually using deposition techniques such as ALD, CVD, LCVD, etc.

Referring to FIG. 5B, the dimensions of the phase change memory area 598 of the intermediate phase change memory array 500 is depicted, according to some embodiments. These dimensions are example dimensions of a phase change memory array, however intermediate PCM array 500 may have any dimensions. In PCM area 598, layer 570 may be 400 nm thick (i.e., has a height of 400 nm), layer 560 may be 287.5 nm thick (i.e., has a height of 287.5 nm), layer 510 may be 62.5 nm thick (i.e., has a height of 62.5 nm), layer 520 may be 30 nm thick (i.e., has a height of 30 nm), layer 530 may be 75 nm thick (i.e., has a height of 75 nm), and layer 540 may be 20 nm thick (i.e., has a height of 20 nm). These measurements may be example measurements for a PCM area 598 of a PCM array, however PCM arrays may include any dimensions. However, knowing the dimensions of the various components of the PCM area 598 and the intermediate PCM array 500 prior to the selective stop process may help the accuracy of the selective stop process (discussed further herein).

In PCM area 598, heating layers 552, 554, and 556 may together have a height (dimension 557) of 31 nanometers (nm). This dimension 557 may be referred to herein as the heater stack height 557. The individual dimensions of each layer 552, 554, and 556 may vary depending on the material(s) of the layers. In an example, heating layer 552 may be a TaN layer and may have a height of 5 nm; heating layer 554 may be a TiN layer and may have a height of 6 nm; and heating layer 556 may be another TaN layer and may have a height of 20 nm. In PCM area 598, there may be 506 nm (dimension 558) between each heater and 372 nm (dimension 528) between each bottom electrode. In some instances, components 565 may have a height (dimension 567) of 450 nm, a width (dimension 566) of 5.6×230 nm, or 1288 nm, and there may be 272 nm between each component 565 (dimension 568). Although there is one width dimension 566 depicted for components 565, there may be slightly different widths of the component 565 at different heights.

Only the dimensions of the phase change memory portion 598 of the intermediate PCM array 500 are depicted in FIG. 5B, however the same/similar measurements may apply to the other areas (e.g., non-PCM area 596 and dummy area 594) of intermediate PCM array 500.

FIG. 6A depicts an intermediate step of forming a phase change memory array after a first selective stop, according to some embodiments. The PCM array after the first selective stop may be referred to herein as intermediate PCM array 600. The first selective stop removes the excess heater materials (i.e., the heater stack) above layer 540. However, the removal process stops at layer 540, resulting in the first selective stop. To remove the excess heater materials and perform the first selective stop, CMP may be used. CMP uses a slurry (which may be an abrasive chemical slurry) to remove the material as well as a polishing pad to polish the material. Specifically, the combination of the chemical slurry and the physical pad may remove the excess heater materials while also planarizing and smoothing the newly exposed surface. Further, as the first selective stop process is only intending to remove the excess heater materials from heater layers 552, 554, and 556, the removal process can be very selective, and the chemistry (for example, the chemical slurry) used in the planarization/removal process may be selective and specific to the metal layers being removed. This may help prevent any excess material from being removed during the CMP of the first selective stop.

Put differently, different slurries (i.e., chemicals) may be used during different steps/CMPs of the selective stop process in order to remove only the wanted materials. For example, to remove the excess heater materials, which are metal materials, a slurry containing silica and water (or any other silica-based solution) can be used to remove the metal heater material(s). The silica-water slurry (or any other silica-based slurry) may remove the heater material(s) at a much faster polish rate (for example, at least 10 times faster) than it may remove the dielectric material (e.g., SiN) of layer 540. This way, the chemical slurry material used in the first selective stop step to remove the excess heater material may quickly, easily, and efficiently remove the excess heater material, but may have a hard time removing any dielectric material from layer 540. The CMP process may slow down significantly once it finished removing the excess heater material and hit layer 540, which may make it far easier to stop the CMP at a very precise point. Further, in some instances, the polish time (discussed further herein) needed to remove the excess heater material(s) may be known and determined prior to the first selective stop.

FIG. 6B depicts the dimensions of the phase change memory portion 598 of the phase change memory array 600 after the first selective stop, according to some embodiments. As discussed in relation to FIG. 5B, there may be precise dimensions/measurements used when forming the intermediate PCM array 500 and/or intermediate PCM array 600. Knowing the measurements of the different layers may help with determining the polish time for each selective stop. For instance, as mentioned in relation to FIG. 6A, different chemical slurry materials may have different removal rates depending on the material(s) of the layers being removed. For example, a silica-based slurry may remove metal layers (for example, TaN and/or TiN) at a relatively fast rate, whereas a slurry such as ZrO₂ may not be good and/or efficient at removing metal layers. Therefore, when removing a specific layer (or layers), such as the excess heater material, it is beneficial to know the specific removal rate that a chemical slurry will have at removing the specific layer, as the removal rate can be used to determine the polish time (i.e., the time needed for the slurry to remove the specific layer(s)) which can help prevent any of the next layer (e.g., layer 540) from being removed during the first selective stop. Further, as discussed above, a silica-based slurry may be slower at removing 10× faster than its removal of dielectric layers such as SiN. Therefore, when both the height/thickness of a layer as well as the removal rate of the chemical slurry are known, the polish time needed to remove the material(s) (for example, the excess heater materials) may be determined. Then, the polish time for the first selective stop may be programed for the calculated time. In some instances, as discussed in FIG. 5B, the height of the excess heater materials (i.e., the height of the heater stack) 557 may be 31 nm, therefore the polish time for the CMP may be calculated using this height and the CMP may be set/selected to stop after the polish time.

After the first selective stop, dimensions 558, 528, 568, 566, and 567 may remain the same as they were in FIG. 5B. Further, the thicknesses/heights of the various layers 580, 560, 510, 520, 530, and 540 may remain the same. After the removal of the excess heater materials (i.e., the 31 nm height (dimension 557) of the heater stack), the heaters 550 may have a height 555 of 95 nm. The remaining portions of layers 552, 554, and 556 may be referred to collectively as heaters 550, herein, and FIG. 6B depicts heaters 550c and 550d.

In some instances, prior to the second selective stop to remove layer 540, the height of layer 540 may be measured. In intermediate PCM array 600, the height (i.e., thickness) of layer 540 may be 20 nm. This measurement may be used to determine the polish time (i.e., the amount of time for the CMP process for the second selective stop), and the CMP may be set to stop after the polish time, in some instances. Specifically, the first selective stop removes the necessary excess heater material without going too far and removing some of the dielectric layer 530. Sacrificial dielectric layer 540 may serve as a buffer to help prevent the first selective stop from removing any of dielectric layer 530. In some instances, the first selective stop may not remove any of dielectric layer 540 or dielectric layer 530 (for example, due to knowing the polish time of the CMP and the chemical slurry for the excess heater materials). In addition, the first selective stop may serve as a point at which layer 540 may be measured, as layer 540 may be measured after the first selective stop. This way, even if the CMP process for the first selective stop removed some of layer 540, the remaining layer 540 may be measured after the first selective stop. The polish time for the second selective stop CMP may be very accurately calculated using the layer 540 measurement taken after the first selective stop, as this measurement may reflect the exact thickness/height of layer 540 (or the remaining layer 540) before its removal. Having an accurate polish time for the second selective stop may increase the accuracy and decrease any chance of excess removal (for example, compared to a single selective stop step to remove the materials up to layer 530) when removing layer 540. This may decrease/prevent any removal of layer 530. Further, this may decrease any variation between heater height for the different heaters in the phase change memory array, as the removals are much more precise and consistent for each heater.

In some instances, the measurements of each layer may all be measured/known prior to the first selective stop, and the polish time for the second selective stop (i.e., the polish time to remove layer 540) may be based on the predetermined measurement of layer 540 that was determined prior to any removal.

FIG. 7A depicts a phase change memory array 700 after a second selective stop, according to some embodiments. PCM array 700 may include fully formed heaters 550a, 550c, and 550d (referred to collectively as heaters 550). The second selective stop removed dielectric layer 540 (the sacrificial dielectric layer) from the PCM array 700. As discussed herein, dielectric layer 540 may be SiN, in some instances. Similar to the first selective stop, CMP may be used to perform the second selective stop.

To perform the second selective stop, a second CMP process with a different chemical slurry may be used. For instance, after the first CMP and the removal of the excess heater materials, the CMP may stop (resulting in the first selective stop) and may be adjusted with a new polish time and/or a new slurry material for the second selective stop to remove dielectric layer 540. As discussed herein, each selective stop (i.e., each CMP) may be tailored/selective to the specific material(s) being removed. Therefore, a chemical slurry that is good at removing dielectric layer 540 (but that may not be good at removing a different type of dielectric such as SiO₂) may be used in the second selective stop. For example, when the dielectric layer 540 is SiN, the SiN layer 540 may be polished using a slurry containing cerium oxide (CeO₂), zirconium oxide (ZrO₂), etc. Slurries containing these materials may be much faster at removing a material such as SiN and may be very slow at removing a material such as SiO₂, therefore the CMP process may be stopped before any SiO₂ is removed. In some instances, a specific slurry and a pH value can be used to remove layer 540 and not layer 530. For example, the pH of the CeO₂ or the ZrO₂ slurry may range from 9-13. In some instances, the length of the CMP (i.e., the polish time) may be determined using the height of the dielectric layer 540 and the material(s) of the chemical slurry.

By having two selective stops and two different steps of removal, any variation during the CMP process may be absorbed in the removal of dielectric layer 540. For example, if there was a single CMP removal process to remove both the excess heater materials as well as dielectric layer 540, at least 51 nm of material may be removed in a single CMP step. Removing a larger amount of material in a single step may result in a greater risk of height variation during the CMP process. Further, in this example, the removal would include both metal materials (from the excess heater materials) as well as dielectric (from the SiN layer 540) which may result in a less selective and less accurate CMP process. In another example, if both layers 530 and 540 were a same dielectric material (instead of different dielectric materials SiN and SiO₂), then the CMP process may have a harder time stopping at the exact measurement, and there may be a higher risk that additional material may be removed and polished, resulting in a higher height variation for the heaters 550. In addition, as discussed herein, a chemical slurry material may have different polish times (i.e., polish rates) depending on the material that is being removed. Therefore, removing multiple materials using a single chemical slurry may decrease the accuracy of the removal, as it may be hard to predict when to stop the CMP process due to the differing polish times/rates.

By including the sacrificial dielectric layer 540 in the intermediate PCM array (e.g., 500 and/or 600 (FIGS. 5A and 6A, respectively)), the CMP removal process for the second selective stop can be very selective and may be specific to the dielectric material of layer 540. Further, the SiN material used for the sacrificial dielectric layer 540 may have a higher thermal conductivity than the SiO₂ dielectric layer 530. Using different dielectric materials helps the CMP only remove layer 540 and not layer 530 (as chemical slurries, such as CeO₂ or ZrO₂ may remove an SiN material without removing an SiO₂ material). In addition, the sacrificial dielectric layer 540 is very thin (e.g., 20 nm) in some instances, which may further help with the control and precision of the CMP process. The second selective stop stops at the dielectric layer 530, in some instances.

In some instances, a third selective stop is performed to remove a portion of dielectric layer 530 as well as a portion of heaters 550. This may decrease the height of the heaters 550. For instance, the heater may have a height of 75 nm after the second selective stop and the removal of sacrificial dielectric layer 540. However, it may be beneficial for the system to have shorter heaters (for example, with a height of 50 nm). For example, current may transmit more quickly from bottom electrodes 525 through heaters 550 if the heaters have a shorter height, as there is less distance to travel. Therefore, in some instances, a third selective stop may be performed to remove excess material and reduce the heater height to 50 nm. The third selective stop may be another CMP, in some instances. In some instances, the third selective stop is part of the second selective stop, and the second selective stop may remove dielectric layer 540 as well as the portion of dielectric layer 530 and the portion of heaters 550.

After the second selective stop, or the third selective stop in some instances, a PCM material and top electrode (not depicted) may be added on top of the heaters 550 to finish forming the PCM array 700, similar to or the same as PCM 400 (and PCM material 160 and top electrode 170) depicted in FIG. 4.

FIG. 7B depicts the dimensions of the phase change memory portion of the phase change memory array after the second selective stop, according to some embodiments. After the second selective stop and the removal of sacrificial layer 540, the heaters 550 may have a heater height 559 of 75 nm. This may be the same height as dielectric layer 530 (which also has a height/thickness of 75 nm), as either none of the dielectric layer 530 may have been removed in the CMP removal process of the second selective stop or a same amount (a very small amount) of layer 530 and heaters 550 were removed (i.e., the removal was consistent for each heater 550). In some instances, either as part of the second selective stop or a third selective stop, the heater height 559 and the height/thickness of layer 530 may be reduced to 50 nm, as discussed herein.

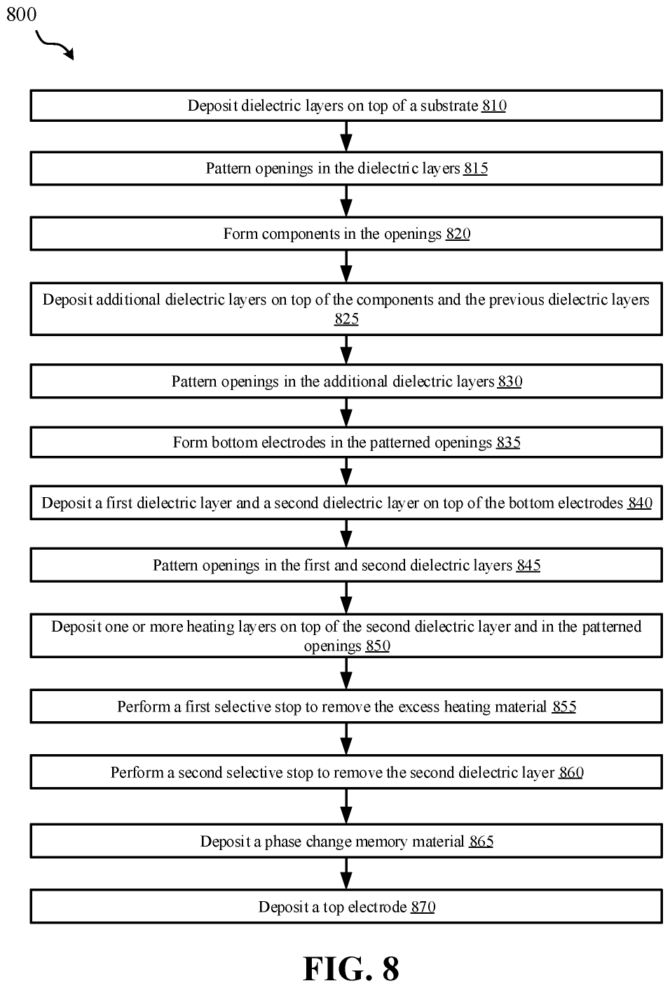

Referring to FIG. 8, a flowchart of an exemplary method 800 of forming a phase change memory array (such as phase change memory array 700) using selective stop is depicted, according to some embodiments. Method 800 includes operation 810 to deposit dielectric layers on top of a substrate. This may include depositing layers 570 and 560 on top of substrate 580 (FIGS. 5A-7B) in some instances. In operation 815, an opening/via is patterned (for example, using reactive ion etching (RIE)) in the dielectric layers. This may create space for device components (for example, components on a chip and/or circuit). In operation 820, the components are formed in the created opening(s). As discussed herein, these components may be substrates, electrodes, connectors, etc. For example, although phase change memory array 700 only includes components 565, additional components may be included below components 565. In these instances, operations 810-820 may have been executed for the additional components. In addition, although phase change memory array 700, for example, includes two layers 560 and 570 of dielectric surrounding components 565, any number of dielectric layers may be used.

Once all the necessary components are formed, method 800 may proceed to operation 825 to deposit additional dielectric layers on top of the components and the previous dielectric layers. This may include depositing layers 510 and 520, in some instances. For example, although phase change memory array 700 includes two additional dielectric layers, any number of dielectric layers may be deposited in operation 825. Similar to operation 815, operation 830 includes patterning openings in the additional dielectric layers. Patterning the openings allows the bottom electrodes to be formed in the patterned openings in operation 835. For PCM array 700, this may include forming bottom electrodes 525.

Method 800 also includes operation 840 to deposit a first dielectric layer and a second dielectric layer on top of the bottom electrodes. This may include depositing SiO₂ layer 530 and the sacrificial SiN layer 540 (FIG. 5A-6B). As discussed herein, depositing two different dielectric layers with two different materials helps encourage a selective CMP removal process (i.e., a selective stop) and prevents unnecessary material from being removed. Through the multi-step selective stop process, the heater height variation among the various heaters in the. PCM array (e.g., heaters 550 in the PCM array 700) may be minimal. Once the first and second dielectric layers are deposited, openings may be patterned in the layers (operation 845) and heating layers may be deposited on top of the second dielectric layers and in the patterned openings (operation 850).

In operation 855, a first selective stop is performed to remove the excess heating material. This excess heating material may be the heater stack, as discussed herein. The chemical slurry in this first selective stop may be selected based on having both a high polish rate for the excess heating material and a low polish rate for the second dielectric layer. Once the excess heating material is removed, operation 860 performs a second selective stop to remove the second dielectric layer. The second dielectric layer may be a sacrificial dielectric layer (such as dielectric layer 540 (FIGS. 5A-6B)). The chemical slurry in this second selective stop may be selected based on having both a high polish rate for the second dielectric layer and a low polish rate for the remaining dielectric and electrode materials. Once the second dielectric layer is removed, a phase change memory material may be deposited on top of the heaters/heating materials. In some instances, a single layer of phase change material is deposited across the phase change memory array. In some instances, a different section of phase change material is deposited over each heater/heating material. Lastly, to finish forming the phase change memories within the phase change memory array, operation 870 includes depositing a top electrode on top of each phase change memory material. In some instances, there may be a different top electrode for each corresponding bottom electrode.

Method 800 discusses the steps that may be used to form a larger PCM array (e.g., PCM array 700) as well as a smaller PCM array (e.g., PCM array 200). For example, to form PCM array 200, method 800 may begin at operation 825, however the dielectric layers in operation 825 may be deposited on top of a substrate instead of the previous dielectric layers. It should be understood that method 800 is an exemplary method showing one possible method of forming a PCM array.

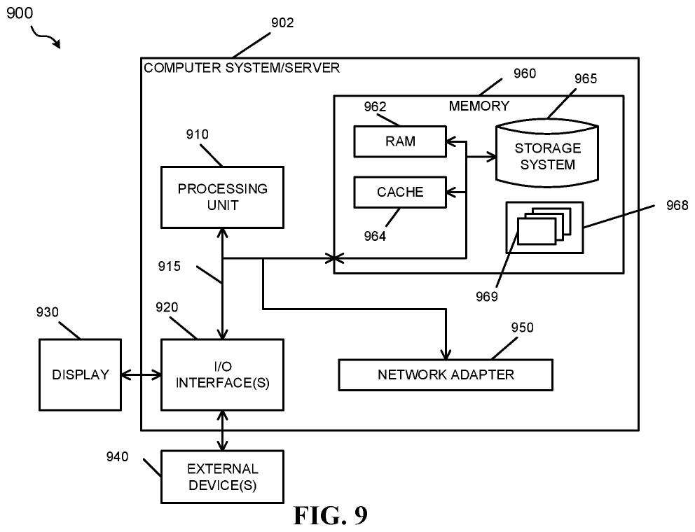

Referring to FIG. 9, computer system 900 is a computer system/server 902 is shown in the form of a general-purpose computing device, according to some embodiments. In some embodiments, computer system/server 902 is located on the linking device. In some embodiments, computer system 902 is connected to the linking device. The components of computer system/server 902 may include, but are not limited to, one or more processors or processing units 910, a system memory 960, and a bus 915 that couples various system components including system memory 960 to processor 910.

Bus 915 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 902 typically includes a variety of computer system readable media. Such media may be any available media that is accessible by computer system/server 902, and it includes both volatile and non-volatile media, removable and non-removable media.

System memory 960 can include computer system readable media in the form of volatile memory, such as random-access memory (RAM) 962 and/or cache memory 964. Computer system/server 902 may further include other removable/non-removable, volatile/non-volatile computer system storage media. By way of example only, storage system 965 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 915 by one or more data media interfaces. As will be further depicted and described below, memory 960 may include at least one program product having a set (e.g., at least one) of program modules that are configured to carry out the functions of embodiments of the disclosure.

Program/utility 968, having a set (at least one) of program modules 969, may be stored in memory 960 by way of example, and not limitation, as well as an operating system, one or more application programs, other program modules, and program data. Each of the operating system, one or more application programs, other program modules, and program data or some combination thereof, may include an implementation of a networking environment. Program modules 969 generally carry out the functions and/or methodologies of embodiments of the invention as described herein.

Computer system/server 902 may also communicate with one or more external devices 940 such as a keyboard, a pointing device, a display 930, etc.; one or more devices that enable a user to interact with computer system/server 902; and/or any devices (e.g., network card, modem, etc.) that enable computer system/server 902 to communicate with one or more other computing devices. Such communication can occur via Input/Output (I/O) interfaces 920. Still yet, computer system/server 902 can communicate with one or more networks such as a local area network (LAN), a general wide area network (WAN), and/or a public network (e.g., the Internet) via network adapter 950. As depicted, network adapter 950 communicates with the other components of computer system/server 902 via bus 915. It should be understood that although not shown, other hardware and/or software components could be used in conjunction with computer system/server 902. Examples include, but are not limited to: microcode, device drivers, redundant processing units, external disk drive arrays, RAID systems, tape drives, and data archival storage systems, etc.

The present invention may be a system, a method, a computer program product, etc. at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electronic signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object orientated program language such as Smalltalk, C++, or the like, and procedural programming languages, such as the “C” programming language or similar programming languages. The computer readable program instructions may execute entirely one the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to some embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming a phase change memory array, the method comprising:
depositing a first dielectric layer;
depositing a second dielectric layer proximately connected to the first dielectric layer, wherein the second dielectric layer is different than the first dielectric layer;
depositing a heating material;
performing a first selective stop to remove excess heating material above the second dielectric layer; and
performing a second selective stop to remove the second dielectric layer.

2. The method of claim 1, wherein the first selective stop and the second selective stop use different chemical slurries.

3. The method of claim 1, wherein:
the first selective stop is performed using chemical mechanical polishing with a first chemical slurry specific to the excess heating material; and
the second selective stop is performed using chemical mechanical polishing with a second chemical slurry specific to the second dielectric layer.

4. The method of claim 2, wherein the first chemical slurry is a silica-based solution.

5. The method of claim 2, wherein the second chemical slurry includes at least one of CeO₂ and ZrO₂.

6. The method of claim 1, further comprising:
after performing the first selective stop, measuring a height of the second dielectric layer; and
calculating a polish time for the second selective stop using the height of the second dielectric layer.

7. The method of claim 1, wherein:
the first selective stop stops after a first polish time and the second selective stop stops after a second polish time;
the first polish time is determined based on a height of the excess heating material and a material of a first chemical slurry; and
the second polish time is determined based on a height of the second dielectric material and a material of a second chemical slurry.

8. The method of claim 1, further comprising:
patterning one or more openings in the first dielectric layer and the second dielectric layer; wherein the depositing the heating material includes depositing the heating material in the one or more openings.

9. The method of claim 8, wherein:
the one or more openings comprise a first opening and a second opening;
the first opening is patterned in a phase change memory area and the second opening is patterned in a dummy area of the phase change memory array; and
no openings are patterned in a non-phase change memory area of the phase change memory array.

10. The method of claim 1, further comprising:
performing a third selective stop to remove a portion of the first dielectric layer and a portion of the heating material.

11. The method of claim 1, wherein the first dielectric layer comprises SiO₂ and the second dielectric layer comprises SiN.

12. A phase change memory array with minimal variation between heater height, wherein the phase change memory array is formed by:
depositing a first dielectric layer;
depositing a second dielectric layer proximately connected to the first dielectric layer, wherein the second dielectric layer is different than the first dielectric layer;
depositing a heating material;
performing a first selective stop to remove excess heating material above the second dielectric layer; and
performing a second selective stop to remove the second dielectric layer.

13. The phase change memory of claim 12, wherein:
the first selective stop is performed using chemical mechanical polishing with a first chemical slurry specific to the excess heating material; and
the second selective stop is performed using chemical mechanical polishing with a second chemical slurry specific to the second dielectric layer.

14. The phase change memory array of claim 13, wherein the first chemical slurry is a silica-based solution.

15. The phase change memory array of claim 13, wherein the second chemical slurry includes at least one of CeO₂ and ZrO₂.

16. The phase change memory of claim 12, wherein the phase change memory is further formed by:
after performing the first selective stop, measuring a height of the second dielectric layer; and
calculating a polish time for the second selective stop using the height of the second dielectric layer.

17. The phase change memory of claim 12, wherein:
the first selective stop stops after a first polish time and the second selective stop stops after a second polish time;
the first polish time is determined based on a height of the excess heating material and a material of a first chemical slurry; and
the second polish time is determined based on a height of the second dielectric material and a material of a second chemical slurry.

18. A system comprising:
a phase change memory array with minimal variation between heater height, wherein the phase change memory array is formed by:
depositing a first dielectric layer;
depositing a second dielectric layer proximately connected to the first dielectric layer, wherein the second dielectric layer is different than the first dielectric layer;
depositing a heating material;
performing a first selective stop to remove excess heating material above the second dielectric layer; and
performing a second selective stop to remove the second dielectric layer.

19. The system of claim 18, wherein:
the first selective stop is performed using chemical mechanical polishing with a first chemical slurry specific to the excess heating material; and
the second selective stop is performed using chemical mechanical polishing with a second chemical slurry specific to the second dielectric layer.

20. The system of claim 18, wherein:
the first selective stop stops after a first polish time and the second selective stop stops after a second polish time;
the first polish time is determined based on a height of the excess heating material and a material of a first chemical slurry; and
the second polish time is determined based on a height of the second dielectric material and a material of a second chemical slurry.
